(19) United States
(12) Patent Application Publication
(10) Pub. No.: US 2015/0296609 A1
(43) Pub. Date: Oct. 15, 2015

(54) MULTI-CIRCUIT-LAYER CIRCUIT BOARD

(71) Applicant: SUNPLUS TECHNOLOGY CO., LTD., Hsinchu Science Park (TW)

(72) Inventor: Chin-Ta HSU, Hsinchu City (TW)

(73) Assignee: SUNPLUS TECHNOLOGY CO., LTD., Hsinchu Science Park (TW)

(21) Appl. No.: 14/248,713

(22) Filed: Apr. 9, 2014

(51) Int. Cl. H05K 1/02

(52) U.S. Cl. CPC H05K 1/0227; H05K 1/0298

(57) ABSTRACT

A multi-circuit layer circuit board includes: two circuit layers formed on a substrate, the same circuit layer including a plurality of signal lines and a plurality of ground reference planes. At least one of the signal lines is formed between any two adjacent ground reference planes. The ground reference planes of one circuit layer are electrically coupled to the ground reference planes of the other circuit layer via a plurality of vias. One of the signal lines of one circuit layer is not overlapped with one signal line of the other circuit layer. The signal lines have a toggle rate higher than 800 MHz.

### BACKGROUND

1. Technical Field

The disclosure relates in general to a multi-layer printed circuit board (PCB), and more particularly to a multi-layer printed circuit board capable of reducing cross-talk noise.

2. Description of the Related Art

High speed digital system design emphasizes high speed, high integrated density, and particularly low cost. High speed digital system design reduces the number of circuit layers used in a printed circuit board (PCB), so that the cost can be reduced accordingly.

In routing of signal lines on a PCB, considered are the following factors such as whether the reference planes for the signal lines are complete, whether the cross-talk noise between the signal lines is serious, and whether the total width of the circuit board may be reduced.

As the toggle rate for the signal lines is getting higher and higher, how to design a multi-circuit layer circuit board capable of operating at a high toggle rate has become a prominent task for the industries.

### SUMMARY OF THE DISCLOSURE

The disclosure is directed to a dual-circuit layer printed circuit board. A plurality of signal lines are interleaved disposed on two adjacent circuit layers, and the spaces between the signal lines on the same circuit layer can be increased. Thus, the cross-talk noise and the total width of the circuit board may both be reduced.

The disclosure is directed to a dual-circuit layer printed circuit board. The signal lines disposed on two adjacent circuit layers are not vertically overlapped with each other, so that the reference planes for the signal lines may be complete.

According to one embodiment of the present disclosure, a multi-circuit layer circuit board is provided. The multi-circuit layer circuit board includes two circuit layers formed on a substrate. The same circuit layer includes a plurality of signal lines and a plurality of ground reference planes. At least one of the signal lines is formed between any two adjacent ground reference planes. The ground reference planes on one circuit layer are electrically coupled to the ground reference planes on the other circuit layer via a plurality of vias. One of the signal lines on one circuit layer is not overlapped with the signal line on the other circuit layer. The signal lines have a toggle rate higher than 800 MHz.

The above and other aspects of the disclosure will become better understood with regard to the following detailed description of the preferred but non-limiting embodiment (s). The following description is made with reference to the accompanying drawings.

### BRIEF DESCRIPTION OF THE DRAWINGS

FIG. 1 is a perspective diagram of a dual-circuit layer printed circuit board according to an embodiment of the disclosure.

FIG. 2 is a cross-sectional view of a dual-circuit layer printed circuit board according to an embodiment of the disclosure.

FIG. 3 is a bird-view view of a dual-circuit layer printed circuit board according to an embodiment of the disclosure.

FIG. 4 is a schematic diagram of a coplanar waveguide with lower ground plane (CPWG).

FIG. 5 is a cross-sectional view of a dual-circuit layer printed circuit board according to another embodiment of the disclosure.

FIG. 6 is a dual-circuit layer printed circuit board according to an alternate embodiment of the disclosure.

### DETAILED DESCRIPTION OF THE DISCLOSURE

Technical terms of the disclosure are based on general definition in the technical field of the disclosure. If the disclosure describes or explains one or some terms, definition of the terms is based on the description or explanation of the disclosure. Description of common technologies or principles of this technical field will be omitted if they are not related to technical features of the application. Shapes, sizes and ratios of the objects are exemplary for one skilled person in the art to understand the disclosure, not to limit the scope of the disclosure.

Each of the disclosed embodiments has one or more technical features. In possible implementation, one skilled person in the art would selectively implement part or all technical features of any embodiment of the disclosure or selectively combine part or all technical features of the embodiments of the disclosure based on the disclosure of the disclosure and his/her own need.

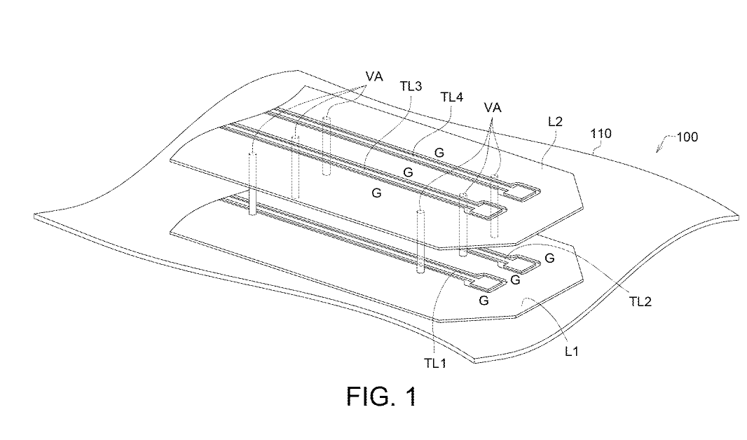

Referring to FIG. 1-FIG. 3, a perspective diagram, a cross-sectional view and a bird view of a dual-circuit layer printed circuit board 100 according to an embodiment of the disclosure are respectively shown. The multi-circuit layer printed circuit board 100 may be realized by such as a dual-circuit layer printed circuit board. For convenience of elaboration, each layer of the multi-circuit layer printed circuit board 100 illustrated in FIG. 1-FIG. 3 includes 2 signal lines, but the disclosure is not limited thereto. In practical implementation, the circuit layer of the printed circuit board may include more signal lines, and such design is still within the spirit of the disclosure.

As indicated in FIG. 1, the printed circuit board 100 includes two circuit layers L1˜L2 formed on a substrate 110. The circuit layer L1 includes signal lines TL1˜TL2. The circuit layer L2 includes signal lines TL3˜TL4. The circuit layer L1 is coupled to the L2 via a plurality of vias VA. In FIG. 1, the designation “G” represents a ground reference plane. FIG. 1 shows that in an embodiment of the disclosure, each of the circuit layers L1 and L2 has a plurality of signal lines, and such design is a key point of the embodiment of the disclosure.

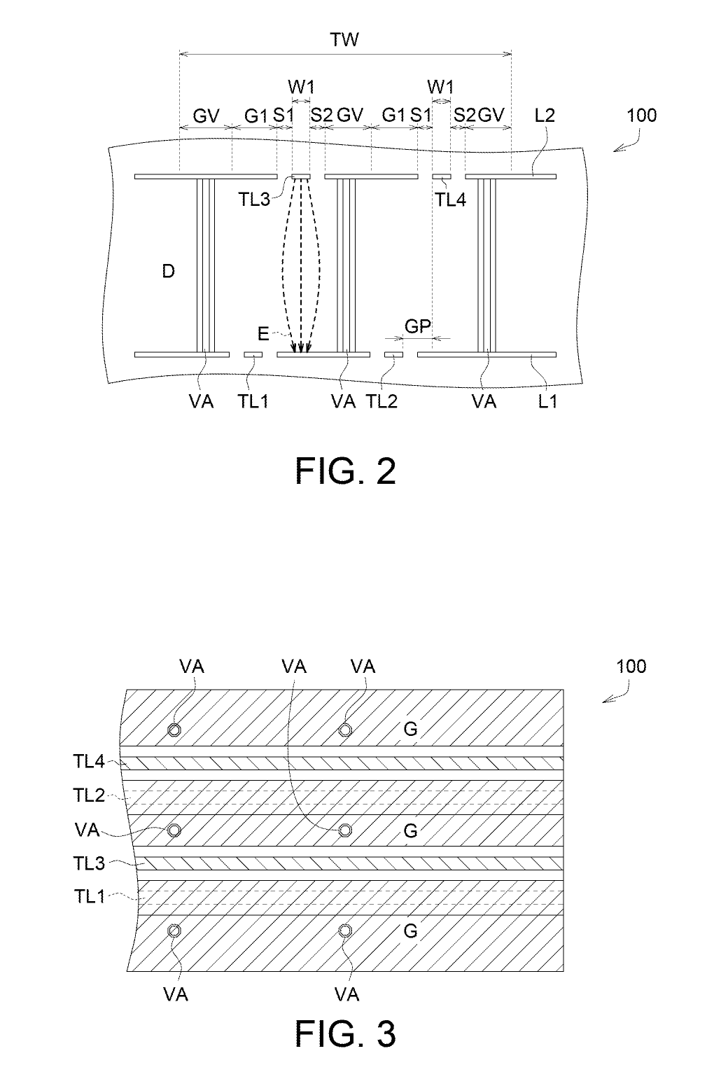

Referring to FIG. 2, a cross-sectional view of a dual-circuit layer printed circuit board 100 according to the embodiment of the disclosure is shown. In FIG. 2, GV represents a width of the via VA, G1 represents a width of the ground reference plane G, S1 represents a space between the signal line and the ground reference plane G, W1 represents a width of the signal line, S2 represents a space between the signal line and the via VA, and D is a dielectric base disposed between the circuit layers L1 and L2.

As indicated in FIG. 1 and FIG. 2, the multi-circuit layer circuit board of an embodiment of the disclosure includes two circuit layers L1 and L2 formed on a substrate 110. The same circuit layer includes a plurality of signal lines and a plurality of ground reference planes. On the same circuit layer, at least one of the signal lines is formed between two adjacent ground reference planes. For example, in FIG. 2, the signal line TL3 is disposed between two adjacent ground reference planes on the circuit layer L1. The ground reference planes on one circuit layer are electrically coupled to the ground reference planes on the other circuit layer via a plurality of vias (FIG. 2). One of the signal lines on one circuit layer is not overlapped with the signal line on the other circuit layer. As indicated in FIG. 2, the signal line TL3 of the circuit layer L2 is not overlapped with the signal line TL1 of the circuit layer L1. In the embodiment of the disclosure, the signal lines, such as signal lines TL1˜TL4, have a toggle rate higher than 800 MHz.

The width G1 of the ground reference plane G affects whether the electromagnetic field of the signal lines, such as the electromagnetic field E of the signal line TL3, has a good reference loop. In the embodiment of the disclosure, the width G1 of the ground reference plane G is wide enough so that the electromagnetic field of the signal line, such as the electromagnetic field E of the signal line TL3, may have a good reference loop.

The size of the via VA has a lower limit. In possible condition, the size GV of the via VA will be designed as the lower limit, so that the total width of the circuit board may be reduced. As technology advances, it is possible that the lower limit of the size of the via VA becomes smaller and smaller.

If signal lines are disposed on the same circuit layer while the other circuit layer does not have any signal lines disposed thereon (such design is not adopted in the embodiment of the disclosure), the total width of the circuit board may not be effectively reduced due to the cross-talk noise between the signal lines. As for the design that all signal lines are disposed on the same circuit layer and the other circuit layer does not have any signal lines disposed thereon, the total width of the circuit board may not be effectively reduced. For example, if a circuit layer has 4 signal lines, then there is a via between two adjacent signal lines, and there is a space between the signal line and the vias at both sides of the signal line, which may negatively affect the total width of the circuit board.

Conversely, in the embodiment of the disclosure as indicated in FIG. 2, because two adjacent circuit layers both have signal lines, a part of the horizontal space between the signal lines on the upper circuit layer is vertically overlapped with the horizontal space between the signal lines on the lower circuit layer and thus, the total width of the circuit board may be reduced. If one circuit layer has signal lines and the other circuit layer does not have any signal lines, the horizontal spaces between the signal lines do not be vertically overlapped with each other and thus, the total width of the circuit board may not be effectively reduced.

As indicated in FIG. 2, to form 4 signal lines on two adjacent circuit layers, the total width TW is expressed as: TW=(GV+G1+S1+S1+S2)*2+GV. Experimental and comparison results show that the total width of the circuit board is effectively reduced in the embodiment of the disclosure.

Further, in the embodiment of the disclosure, the vertical space GP between a signal line on one circuit layer and a corresponding signal line on an adjacent circuit layer satisfies GP≧0. As indicated in FIG. 2, the vertical space GP between one side of the signal line TL4 on the circuit layer L2 and one side of the signal line TL2 on the circuit layer L1 satisfies GP≧0. That is, viewing from a vertical direction of FIG. 2, there is no overlap between the signal lines on one circuit layer and the signal lines on the other circuit layer. In the embodiment of the disclosure, the electromagnetic field of the signal lines may have a good reference loop by such arrangement. That is, if a signal line (for example, the signal line TL4) on one circuit layer is vertically overlapped with a corresponding signal line (for example, the signal line TL2) on the other circuit layer, the electromagnetic field of the signal lines will have an incomplete or discontinuous reference plane. As a result, the impedance will be discontinuous and the cross-talk noise will become severe, which may result that the signals may be distorted during transmission, the normal operation of the circuit may be negatively influenced or even the circuit does not operate at a high frequency. Thus, the embodiment of the disclosure may avoid the above problems.

Refer to FIG. 2 again. In an embodiment of the disclosure, the ground reference plane is disposed on one side of the signal line. As indicated in FIG. 2, a ground reference plane and a via are disposed on the left-hand side of signal line TL4. The horizontal space between two signals on the same circuit layer is larger and thus, the cross-talk noise between the neighboring signal lines may be reduced. As indicated in FIG. 2, the horizontal space between the signal lines TL4 and TL3 on the circuit layer L2 is equal to S2+GV+G1+S1, and such a horizontal space helps to reduce the cross-talk noise between the signal lines TL4 and TL3 because the signal lines TL4 and TL3 are separated by a larger distance.

FIG. 3 is a bird view of the dual-circuit layer printed circuit board 100 according to the embodiment of the disclosure. As indicated in FIG. 3, the signal lines on the upper circuit layer and the signal lines on the lower circuit layer are interleaved with each other. As indicated in FIG. 3, the signal line TL4 of the circuit layer L2, the signal line TL2 of the circuit layer L1, the signal line TL3 of the circuit layer L2 and the signal line TL1 of the circuit layer L1 are disposed in a top down manner. In terms of an upper view, “interleave” refers that one signal line on one circuit layer is interleaved between two signal lines on the other circuit layer. Although the signal lines of two circuit layers are not disposed on the same horizontal plane, the arrangement between the signal lines of two circuit layers as illustrated in FIG. 3 still are referred as interleaved displacement.

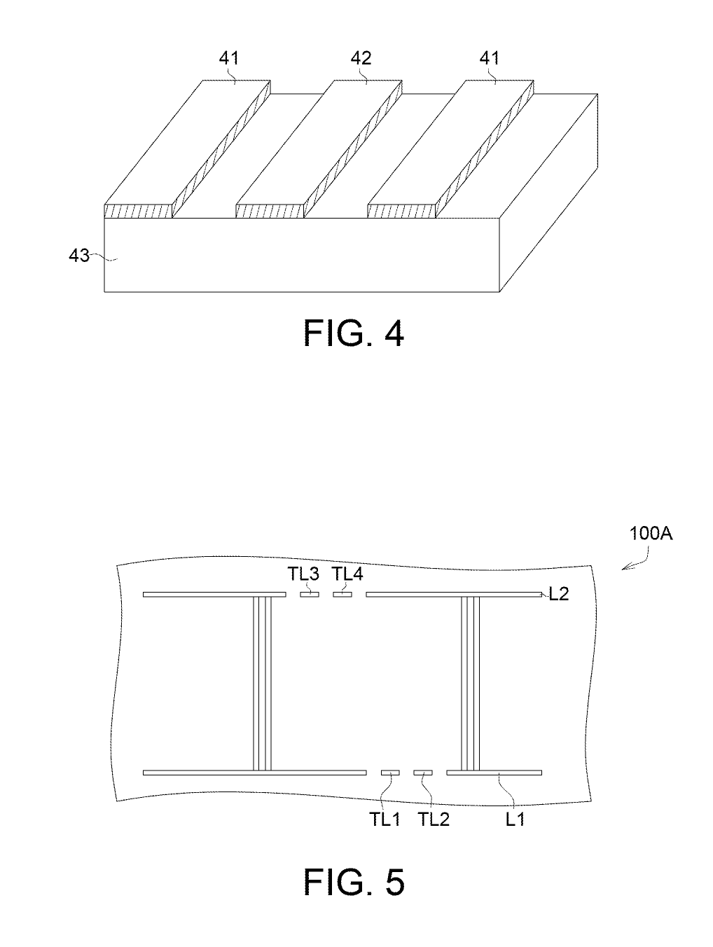

FIG. 4 is a schematic diagram of a coplanar waveguide with lower ground plane (CPWG). As indicated in FIG. 4, a signal transmission conductor 42 (that is, a signal line) and ground metal planes 41 on both sides of the signal transmission conductor 42 are formed on a surface of a dielectric base 43. In an embodiment of the disclosure, two circuit layers L1 and L2 of FIG. 1 both have a CPWG structure.

Refer to FIG. 2 and FIG. 4 at the same time. The signal line TL1 (that is the signal transmission conductor 42 of FIG. 4) and the ground planes G (that are the ground metal planes 41 of FIG. 4) on both sides of the signal line TL1 form a coplanar waveguide. Although the dielectric base is not illustrated in FIG. 2, anyone who is skilled in the technology field of the disclosure will understand that the dielectric base is under the circuit layers L1 and L2.

Referring to FIG. 5, a cross-sectional view of a dual-circuit layer printed circuit board 100A according to another embodiment of the disclosure is shown. Compared with FIG. 2, in FIG. 5, two signal lines are disposed between any two adjacent ground reference planes on the circuit layer. Like FIG. 1 and FIG. 2, the signal line on one circuit layer is not overlapped with the signal line on the other circuit layer. As indicated in FIG. 5, the signal line TL4 of the circuit layer L2 is not overlapped with the signal line TL1 of the circuit layer L1. Besides, the toggle rates of the transmission signals of the signal lines (for example, signal lines TL1˜TL4) are still higher than 800 MHz.

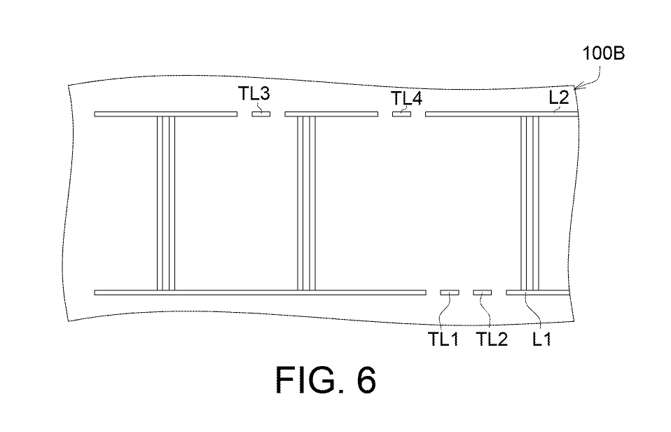

Referring to FIG. 6, a dual-circuit layer printed circuit board 100B according to an alternate embodiment of the disclosure is shown. Compared with FIG. 2, in FIG. 6, a single signal line is formed between any two adjacent ground reference planes on one circuit layer, while two signal lines are disposed between any two adjacent ground reference planes on the other circuit layer. For example, the signal line TL3 is disposed between two adjacent ground reference planes on the circuit layer L2, and two signal lines TL1 and TL2 are disposed between two adjacent ground reference planes on the circuit layer L1. Like FIG. 1 and FIG. 2, the signal line on one circuit layer is not overlapped with the signal line on the other circuit layer. As indicated in FIG. 6, the signal line TL4 of the circuit layer L2 is not overlapped with the signal line TL1 of the circuit layer L1. Besides, the toggle rates of the transmission signals of the signal lines (for example, signal lines TL1˜TL4) are still higher than 800 MHz.

In an embodiment of the disclosure, the signal line on the circuit layer is not overlapped with the signal line on the other circuit layer, so that the reference plane for the signal lines may be complete and signals will not be severely distorted during transmission.

To increase the spaces between the signal lines, in the embodiment of the disclosure, the signal lines are disposed on two adjacent circuit layers, and ground reference planes are disposed between the signal lines on the same circuit layer. Therefore, the horizontal space between the signal lines on the same circuit layer is increased and thus the cross-talk noise is effectively reduced.

Although the horizontal spaces between the signal lines on the same circuit layer are increased, a part of the horizontal space between the signal lines on one circuit layer is vertically overlapped with the horizontal spaces between the signal lines on the other circuit layer. Thus, in the embodiment of the disclosure, the total width of the circuit board is reduced.

While the disclosure has been described by way of example and in terms of the preferred embodiment (s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A multi-circuit layer circuit board, comprising:
two circuit layers formed on a substrate, the same circuit layer including a plurality of signal lines and a plurality of ground reference planes;
wherein
at least one of the signal lines is formed between any two adjacent ground reference planes;
the ground reference planes on one circuit layer are electrically coupled to the ground reference planes on the other circuit layer via a plurality of vias,
one of the signal lines on one circuit layer is not overlapped with the signal line on the other circuit layer; and
the signal lines have a toggle rate higher than 800 MHz.

2. The multi-circuit layer circuit board according to claim 1, wherein,
in a vertical direction, a space between one side of the signal line of the circuit layer and one side of the signal line on the other circuit layer is greater than or equal to 0.

3. The multi-circuit layer circuit board according to claim 1, wherein,
in a vertical direction, the signal line of the circuit layer is interleaved between two adjacent signal lines on the other circuit layer.

4. The multi-circuit layer circuit board according to claim 1, wherein,
on each circuit layer, the signal lines and the ground reference planes form a coplanar waveguide.

5. The multi-circuit layer circuit board according to claim 1, wherein,
a part of a horizontal space between the signal lines of the circuit layer is vertically overlapped with a horizontal space between the signal lines on the other circuit layer.

6. The multi-circuit layer circuit board according to claim 1, wherein,
on each circuit layer, a single signal line is formed between any two adjacent ground reference planes.

7. The multi-circuit layer circuit board according to claim 1, wherein,
on each circuit layer, two signal lines are formed between any two adjacent ground reference planes.

8. The multi-circuit layer circuit board according to claim 1, wherein,
on one of the circuit layers, a single signal line is formed between any two adjacent ground reference planes; and
on another one of the circuit layers, two signal lines are formed between any two adjacent ground reference planes.
